(19) United States
(12) Patent Application Publication
(10) Pub. No.: US 2020/0011650 A1
(43) Pub. Date: Jan. 9, 2020

(54) METROLOGY TARGET

(71) Applicant: Carl Zeiss SMT GmbH, Oberkochen (DE)

(72) Inventor: Hans-Michael STIEPAN, Aalen (DE)

(21) Appl. No.: 16/577,588

(22) Filed: Sep. 20, 2019

Related U.S. Application Data
(63) Continuation of application No. PCT/EP2018/055065, filed on Mar. 1, 2018.

(30) Foreign Application Priority Data
Mar. 21, 2017 (DE) 10 2017 204 719.4

(51) Int. Cl. G01B 9/021; G03H 1/08; G03F 7/20; G01M 11/00

(52) U.S. Cl. CPC G01B 9/021; G03H 1/0808; G03F 7/70408; G03H 2001/0825; G03F 7/70325; G01M 11/005; G03F 7/2022

(57) ABSTRACT

A metrology target having a periodic or quasi-periodic structure, which is characterized by a plurality of parameters. At least one of these parameters varies locally monotonically, wherein the maximum size of this variation over a distance of 5 μm is less than 10% of the size of the at least one parameter. In addition, the metrology target has at least one used structure and at least one auxiliary structure, wherein the auxiliary structure transitions progressively into the used structure with regard to the locally monotonically varying parameter. Also disclosed are an associated method and associated device for characterizing structured elements configured as wafers, masks or CGHs.

### CROSS REFERENCE TO RELATED APPLICATIONS

This is a Continuation of International Application PCT/EP2018/055065, which has an international filing date of Mar. 1, 2018, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2017 204 719.4 filed on Mar. 21, 2017.

### FIELD OF THE INVENTION

The invention relates to a metrology target. Furthermore, the invention also relates to a method and a device for characterizing a structured element in the form of a wafer, a mask or a CGH.

### BACKGROUND

Microlithography is used for producing microstructured components, such as for example integrated circuits or LCDs. The microlithography process is carried out in what is called a projection exposure apparatus, which comprises an illumination device and a projection lens. The image of a mask (=reticule) illuminated with the illumination device is in this case projected by the projection lens onto a substrate (for example a silicon wafer) coated with a light-sensitive layer (photoresist) and arranged in the image plane of the projection lens, in order to transfer the mask structure to the light-sensitive coating of the substrate.

In this case, in practice there is a need to monitor parameters characteristic of the patterned wafer, e.g. the CD value or the layer thickness. Particularly in so-called “multi-patterning” methods for undershooting the resolution limit of the optical system with structures produced on the wafer in a plurality of lithography steps, a large number of process parameters have to be monitored. This includes, in particular, monitoring the relative position of structures produced on the wafer in different lithography steps, the highest possible accuracies (e.g. of the order of magnitude of 1 nm) being striven for. The overlay accuracy determined in this case is often of particular importance and is also referred to as “overlay”.

When determining such parameters it is known, inter alia, to produce auxiliary or marker structures in particular in edge regions of the wafer elements respectively produced, in order to carry out, on the basis of said auxiliary structures, a diffraction-based determination of the respectively relevant parameters in a scatterometric arrangement. In order to make the auxiliary or marker structures accessible to a measurement even at higher orders of diffraction than merely the zero order of diffraction, said auxiliary or marker structures are typically often configured more coarsely or with a greater line spacing than the used structures.

Besides the additional outlay for providing the auxiliary structures, however, in practice the further problem occurs here that the parameter values ascertained on the basis of the comparatively coarse auxiliary structures do not necessarily represent the actual behavior of the used structures actually of interest which are situated on the wafer, which, for example, may be attributable to an insufficient correlation between used structure and auxiliary structure and/or a large distance between them.

A further problem that occurs in practice is that the respectively relevant parameters to be determined using the scatterometric measurement set-up partly correlate among one another with the consequence that obtaining a specific measurement signal cannot be used to directly deduce whether this measurement signal is caused by a variation of a specific parameter (e.g. of the sidewall angle) or e.g. by a specific combination of a variation of other parameters (for example etching depth and edge rounding).

In practice further problems result from the fact that both the scatterometric measurement arrangement itself and the measured sample including the auxiliary or marker structures and the alignment thereof in the measurement arrangement may be beset by uncertainties or faults with the consequence that obtaining a specific measurement signal cannot be used to ascertain unequivocally whether said measurement signal is attributable to a faulty auxiliary or marker structure or to a faulty orientation of the sample in the measurement arrangement.

In a further field of application of the present invention, marker structures are also used in computer-generated holograms (CGHs). Such CGHs are used for example for the highly accurate testing of mirrors. In this case, the realization of a calibration of the CGHs that are used in mirror testing by using so-called complex-encoded CGHs is also known, inter alia, wherein at least one further “calibration functionality” for providing a reference wavefront that serves for calibration or error correction is encoded in one and the same CGH in addition to the “use functionality” (i.e. the CGH structure that is designed in accordance with the mirror shape for shaping the wavefront that mathematically corresponds to the test specimen shape) that is required for the actual test. One problem that occurs here in practice is that in general once again numerous profile parameters (e.g. sidewall angles or feature size (CD)) are required for completely determining the profile of the CGH. Metrology targets are used in CGHs, against this background, as marker structures for determining profile parameters on the basis of simpler structures.

In the CGHs, at transitions between metrology targets and used and/or alignment structures (also called auxiliary structures), undesired physical or chemical processes may possibly take place during the processing, however, which processes may result in an undesired modification or even destruction of the CGH structures situated in direct proximity. This effect may also already occur at the transition between alignment and used structures. The invention present here gives a description of how these undesired effects can be reduced in both of the above cases.

In respect of the prior art, reference is made merely by way of example to U.S. Pat. No. 9,311,431 B2, US 2016/0266505 A1 and WO 2013/138297 A1.

### SUMMARY

Against the above background, it is an object of the present invention to provide a metrology target which makes it possible to avoid one or more of the problems described above.

This and other objects are achieved with a metrology target as described and claimed herein.

In accordance with one aspect, the invention relates to a metrology target, wherein the metrology target has a periodic or quasi-periodic structure, wherein said structure is characterized by a plurality of parameters, wherein at least one of said parameters varies locally monotonically, wherein the maximum size of this variation over a distance of 5 μm is less than 10%, wherein the metrology target has at least one used structure and at least one auxiliary structure, wherein the auxiliary structure transitions progressively into the used structure with regard to the locally monotonically varying parameter.

“Quasi-periodic” is understood here to mean that the variation op of the period p of a periodic structure is slow in relation to a typical wavelength), that is to say that it must hold true that

$$\frac{δ p}{p} << \frac{p}{λ} .$$

In accordance with one embodiment, the maximum size of said variation over a distance of 20 μm, in particular over a distance of 40 μm, is less than 10%.

In accordance with one embodiment, the maximum size of the variation over said distance is less than 5%, in particular less than 1%.

Aspects of the invention are based on the concept, in particular, that a periodic or quasi-periodic structure present on a metrology target and serving e.g. as an auxiliary or marker structure is not configured as an isolated structure that is uniform with regard to all characteristic parameters, rather at least one characteristic parameter (which can be, merely by way of example, the ratio of web width to period in a grating line structure) varies gradually and (quasi-) continuously across the metrology target.

Here “gradual” and “quasi-continuous” variation is taken to mean, in the application of a scatterometric measurement arrangement, that the relevant variation takes place on a scale that is large in comparison with the operating wavelength of the electromagnetic radiation used during the scatterometric measurement, that is to say that analogously to the above definition for a quasi-continuously varying parameter x it must hold true that

$$\frac{δ x}{x} << \frac{p}{λ} .$$

What is achieved with the quasi-continuous variation—in the sense above—of at least one characteristic parameter of the (auxiliary) structure present on the metrology target according to the invention is that, firstly, at each individual location of the structure periodic boundary conditions in the solution of Maxwell's equations are still justified and, secondly, the problems that occur with the use of an isolated auxiliary structure that is inherently constant with regard to all characteristic parameters, as described in the introduction, are avoided.

By virtue of the fact that, in the application of the scatterometric measurement arrangement, for instance, the intensity measurements are not carried out for an isolated, inherently constant auxiliary structure, but rather for a structure that varies quasi-continuously in the sense above, the measurement curves obtained during the intensity measurements, as explained in even greater detail below, can be used in particular for breaking up parameter correlations, since said parameter correlations are also variable across the metrology target which varies as described. This renders it possible in turn as a result to assign the measurement signals obtained (in contrast to a method based on isolated, constant auxiliary structures) to unambiguously determined profile parameters or it is possible—as will be explained in even greater detail—to identify the regions of the metrology target which are particularly suitable in each case for a simultaneous determination of a plurality of profile parameters (in which regions the relevant profile parameters are only weakly correlated).

Furthermore, it is possible—as will likewise be explained in even greater detail—to deduce, on the basis of the intensity measurements carried out with a metrology target according to the invention in the scatterometric arrangement, whether specific measurement signals are attributable to a faulty auxiliary structure or to a faulty alignment of the measurement arrangement.

In embodiments of the invention, the above-described quasi-continuous variation of at least one characteristic parameter of the structure present on the metrology target according to the invention can be constituted in particular in such a way that an auxiliary structure is progressively converted into an adjacent used structure, that is to say, in other words, that the parameter that varies locally monotonically within the auxiliary structure finally corresponds to the parameter in the adjoining used structure.

It is thereby possible, in the application of the scatterometric measurement arrangement, to overcome the problem—described in the introduction—of the difference or insufficient correlation between isolated auxiliary structures, on the one hand, and used structures, on the other hand.

A further advantage of the above-described quasi-continuous and progressive conversion of auxiliary structures into used structures is that said auxiliary structures can be substantially continuously embedded into the surroundings with the consequence that during etching using plasma processes, for instance, no discontinuities are induced in the etching profile. Accordingly, both in the application of the scatterometric measurement arrangement for determining relevant profile parameters of the wafer and in the application of CGHs, it is possible to avoid the problems—described in the introduction—of an undesired modification of the respective used structures by auxiliary structures.

This technique can likewise be used to convert alignment structures and used structures on a CGH continuously into one another.

In accordance with one embodiment, the locally monotonically varying parameter is a geometric parameter.

In accordance with one embodiment, the periodic or quasi-periodic structure is furthermore characterized by at least one constant parameter.

In accordance with one embodiment, at least one of the parameters characterizing the structure is selected from the group of pitch (period), sidewall angle and etching depth.

In accordance with one embodiment, the metrology target is designed for the diffraction-based determination of at least one parameter of a used structure on a structured element in the form of a wafer, a mask or a CGH in a scatterometric measurement arrangement.

In accordance with one embodiment, the metrology target is provided on a computer-generated hologram (CGH).

The invention furthermore relates to a computer-generated hologram (CGH) having a metrology target according to the invention.

In accordance with one embodiment, the metrology target is designed for testing a surface of a mirror by interferometric superimposition of a test wave directed onto the mirror by the CGH and a reference wave, wherein the metrology target is arranged in a region of the CGH that is unused during said interferometric superimposition.

The invention furthermore relates to a computer-generated hologram (CGH) having at least one used structure and at least one alignment structure adjoining the used structure or embedded into the used structure and serving for the alignment of the computer-generated hologram in relation to an interferometric test arrangement, characterized in that the used structure is converted continuously into the alignment structure with regard to at least one characteristic parameter.

In accordance with this aspect, a continuous transition between alignment structure and used structure is thus created, which can be realized for instance by way of the corresponding continuous configuration of at least one complex (weight) function describing the used structure and/or the alignment structure. The above approach is based on the consideration that an abrupt transition between alignment structure and used structure, from a production engineering standpoint, can lead to undesired process variations and (for instance by way of shading effects during plasma etching) to an undesired modification of the used structures (e.g. an abrupt change in the etching depth), which is avoided with a smooth, continuous transition according to the invention between alignment structure and used structure.

The invention furthermore relates to a method for characterizing a structured element in the form of a wafer, a mask or a CGH,
wherein a plurality of parameters characteristic of the structured element are ascertained on the basis of measurements of the intensity of electromagnetic radiation after the diffraction thereof at the structured element, wherein these intensity measurements are carried out for at least one used structure and at least one auxiliary structure situated on a metrology target;
wherein the parameters are ascertained on the basis of intensity values measured during the intensity measurements for respectively different combinations of wavelength, polarization and/or order of diffraction, and also on the basis of correspondingly calculated intensity values, with a mathematical optimization method being applied;
wherein the metrology target is designed in accordance with the features described above.

The invention furthermore relates to a method for characterizing a structured element in the form of a wafer, a mask or a CGH,
wherein a plurality of parameters characteristic of the structured element are ascertained on the basis of measurements of the intensity of electromagnetic radiation after the diffraction thereof at the structured element, wherein these intensity measurements are carried out for at least one used structure and at least one auxiliary structure situated on a metrology target;
wherein the parameters are ascertained on the basis of intensity values measured during the intensity measurements for respectively different combinations of wavelength, polarization and/or order of diffraction, and also on the basis of correspondingly calculated intensity values, with a mathematical optimization method being applied;
wherein the metrology target has a periodic or quasi-periodic structure; and
wherein said structure is characterized by a plurality of parameters, wherein at least one of said parameters varies locally monotonically, wherein the maximum size of this variation over a distance corresponding to ten times an operating wavelength used during the intensity measurements is less than 10%.

In accordance with one embodiment, the intensity measurements are taken as a basis for carrying out a determination of parameter correlations between different parameters characteristic of the structured element for different regions of the metrology target with different values of the locally monotonically varying parameter.

In accordance with one embodiment, the intensity measurements are taken as a basis for carrying out a calibration of the measurement arrangement used during the intensity measurements.

In accordance with one embodiment, the parameters characteristic of the structured element comprise at least one parameter from the group of CD value, etching depth and overlay accuracy of two structures produced in different patterning (e.g. lithography) steps.

In accordance with one embodiment, the intensity measurements are carried out simultaneously for at least two regions on the structured element.

The invention furthermore relates to a device for characterizing a structured element in the form of a wafer, a mask or a CGH, wherein the device is configured to carry out a method having the features described above. With regard to advantages and advantageous configurations of the device, reference is made to the above explanations in association with the method according to the invention.

The invention furthermore relates to a method for testing a surface of a mirror, in particular of a microlithographic projection exposure apparatus, wherein the testing is carried out by interferometric superimposition of a test wave directed onto the mirror by a computer-generated hologram (CGH) and a reference wave, characterized in that the CGH is designed in accordance with the features described above.

Further configurations of the invention can be gathered from the description and the dependent claims.

The invention is explained in greater detail below on the basis of exemplary embodiments that are illustrated in the accompanying figures.

### BRIEF DESCRIPTION OF THE DRAWINGS

FIGS. 1A and 1B show schematic illustrations for explaining an overlay value (FIG. 1A) and sidewall angle (FIG. 1B) determinable in the context of the method according to the invention;

FIG. 2 shows a schematic illustration of one possible embodiment of a measuring arrangement or device for carrying out the method according to the invention;

FIG. 3 shows a schematic illustration of an arrangement of used and auxiliary structures on a wafer for explaining one possible application of the invention;

FIGS. 4A and 4B show, in a macroscopic plan view (FIG. 4A) and a microscopic sectional view (FIG. 4B), schematic illustrations for explaining one possible configuration of a metrology target according to the invention;

FIGS. 5A and 5B show diagrams for explaining an exemplary application of the invention involving etching depth d (FIG. 5A) and tilt angle ϕ FIG. 5B);

FIGS. 6A-6C show diagrams for explaining a further exemplary application of the invention involving etching depth d (FIG. 6A), sidewall angle ε (FIG. 6B), and the ratio v of web width to period (FIG. 6C);

FIG. 7 shows parameter correlations resulting from the exemplary applications of the invention shown in FIGS. 6A-6C;

FIG. 8 shows a schematic illustration of a further exemplary embodiment of the invention using overlay value as the locally varying parameter;

FIGS. 9A and 9B show, with reference to a CGH (FIG. 9A) and a metrology target (FIG. 9B), a schematic illustration of a further exemplary embodiment of the invention;

FIGS. 10A and 10B show, with reference to a complex encoded CGH (FIG. 10A) and a metrology target (FIG. 10B), a schematic illustration of a further exemplary embodiment of the invention;

FIGS. 11A and 11B show, with reference to a regular arrangement of contact holes (FIG. 11A) and the ellipticity of these contact holes (FIG. 11B) as the characteristic parameter, a schematic illustration of another exemplary embodiment of the invention;

FIG. 12 shows, using a marker structure positioned in a CGH, a schematic illustration of yet another exemplary embodiment of the invention; and

FIG. 13 shows a schematic illustration of a further exemplary embodiment of the invention contrasting an abrupt transition with a smooth transition between an alignment structure and a used structure;

### DETAILED DESCRIPTION

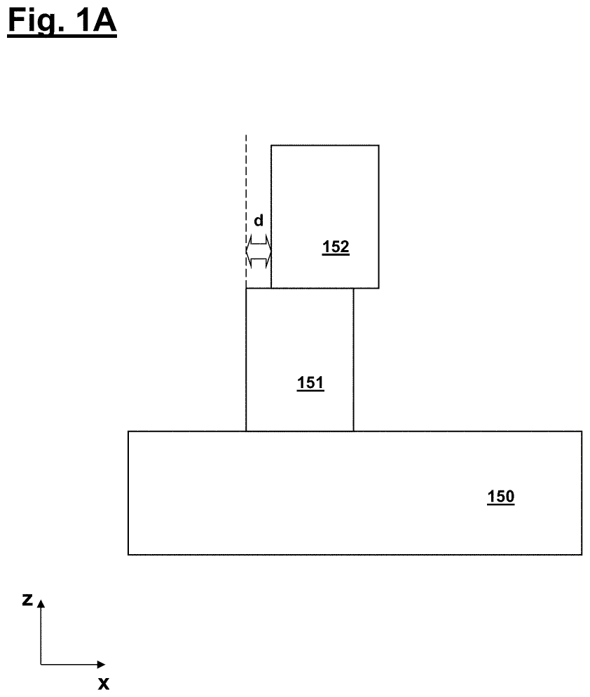

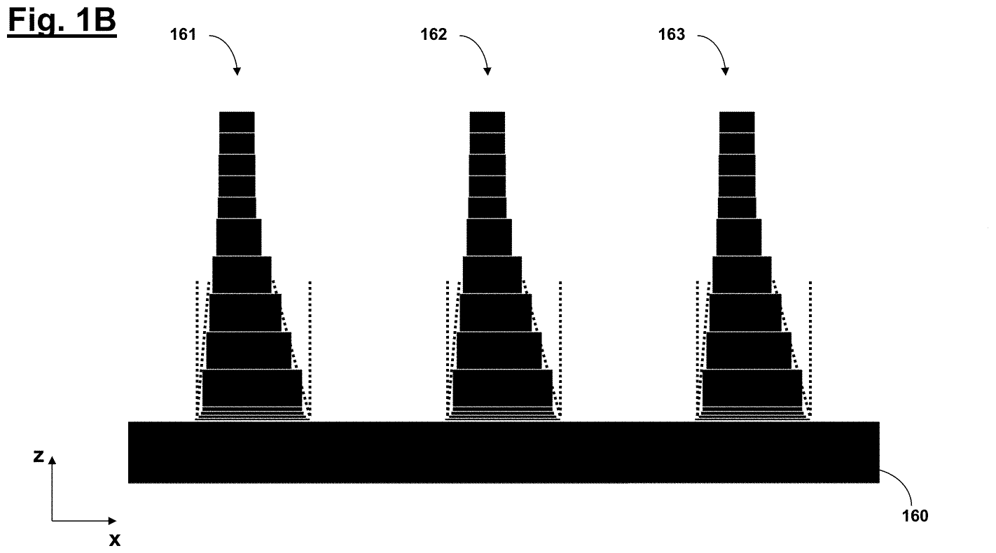

FIGS. 1A-1B firstly show merely schematic, greatly simplified illustrations for describing exemplary parameters determinable in the context of the method according to the invention. FIG. 1A shows merely schematically two structures produced in different lithography steps on a wafer 150, said structures having an offset d, which is determinable according to the invention, in the lateral direction (x-direction in the coordinate system depicted), wherein said offset is determinable as an overlay value. FIG. 1B shows a schematic illustration of typical asymmetrical structures 161-163 produced on account of etching processes on a wafer 160, said structures being characterizable inter alia by sidewall angles that are likewise determinable by the method according to the invention.

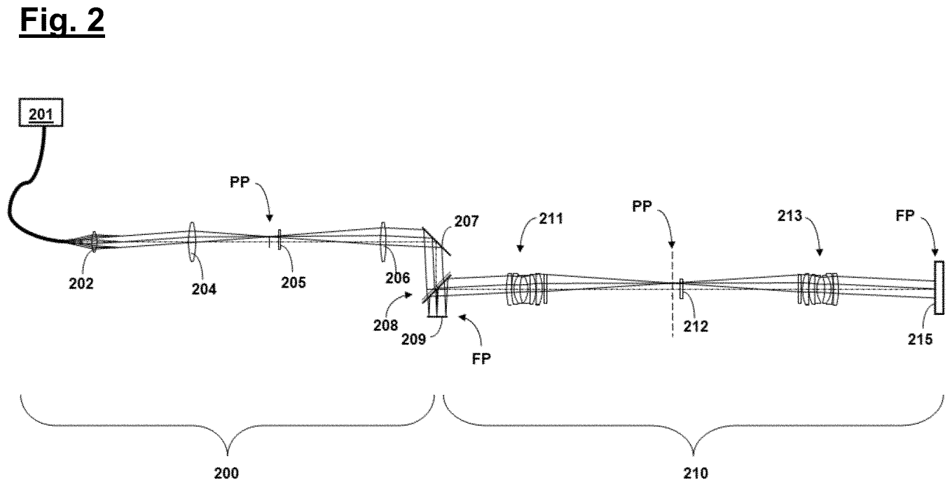

FIG. 2 shows, in a schematic illustration, one possible embodiment of a measuring arrangement or device for carrying out the method according to the invention.

The measuring arrangement in FIG. 2 is configured as a scatterometer and comprises a light source 201, which can be e.g. a broadband tunable light source for generating a wavelength spectrum (for example in the wavelength range of 300 nm to 800 nm). In FIG. 2 the illumination beam path is designated by “200” and the imaging beam path by “210”. The light from the light source 201 passes into a pupil plane PP via an input coupling and also a lens element 202 and an optical unit represented by a further lens element 204. “205” denotes a polarizer for setting desired polarization states (e.g. of linearly polarized light having a predefined polarization direction), wherein different polarization states or polarization directions are settable by variable setting or else exchange of the polarizer 205, depending on the specific configuration thereof. From the polarizer 205, the light in accordance with FIG. 2 is incident, via a lens element 206 or an optical group represented thereby, a deflection mirror 207 and a beam splitter 208, on a wafer 209 or the structures already produced lithographically on said wafer 209, which is situated in the field plane FP and is arranged in a wafer plane on a wafer stage.

After diffraction at said structures, the light in accordance with FIG. 2 passes once again via the beam splitter 208 in the imaging beam path via an optical group 211, an analyzer 212 situated in a pupil plane PP, or in the vicinity thereof, and also a further assembly 213 onto a detector (camera) 215 situated in a field plane FP. Analyzer 212 and polarizer 205 can each be configured in a rotatable fashion. With the use of the tunable light source 201 and/or the polarizer 205, respectively, the intensity measurement can be effected by the detector 215 for a multiplicity of different wavelengths or polarization states. On the basis of the intensity values respectively measured by the detector 215, using comparison (in particular difference formation), e.g. a determination or monitoring of the relative position of structures produced in different lithography steps on the wafer 209 can be performed in a model-based fashion in a manner known per se.

For an overlay determination, e.g. the measurement values obtained for different combinations of polarization and wavelength are fitted in each case to a model produced by solving Maxwell's equations, wherein it is possible to apply e.g. the least square deviation method in iteration. In this case, furthermore, the determination of the overlay value respectively assigned to a patterned wafer region and, if appropriate, of further parameters or characteristic variables (e.g. sidewall angles of asymmetrical structures in accordance with FIG. 1B, CD value, etc.) at each measurement time or in each measurement step is effected not just for a single patterned wafer region, but rather simultaneously for a plurality of wafer regions, i.e. for ascertaining a plurality of overlay values or further characteristic variables, wherein each of said overlay values is respectively assigned to one of the plurality of regions being measured simultaneously.

This is made possible in the measuring arrangement from FIG. 2, in particular, by the imaging from the wafer 209 onto the detector 215 being fashioned such that the imaging or the spot RMS is corrected at a subpixel level of the sensor, e.g. typically to a spot size of less than 5 μm. It is particularly advantageous to use a so-called 1:1 imaging here. Each of the patterned wafer regions mentioned above thus corresponds to a (camera) region imaged onto the respective detector 215. Accordingly, according to the invention, in each measurement step or at each measurement time, not just individual spots (for determining in each case only a single overlay value) are measured, rather a field is imaged onto the relevant detector (camera) 215. In this case, the field imaged according to the invention can have a size of typically a plurality of mm². In this case, merely by way of example, the simultaneously recorded overall region on the wafer can correspond to the size of a typical wafer element or chip (“die”) and have a value of e.g. 26 mm*33 mm. In other words, instead of progressive illumination and diffraction-based measurement of individual structures, an entire field is illuminated, wherein said field, merely by way of example, can have a size of a plurality of mm², e.g. 30 mm*40 mm. In this case, individual wafer regions respectively correspond to a detector region (comprising one or more camera pixels on the detector).

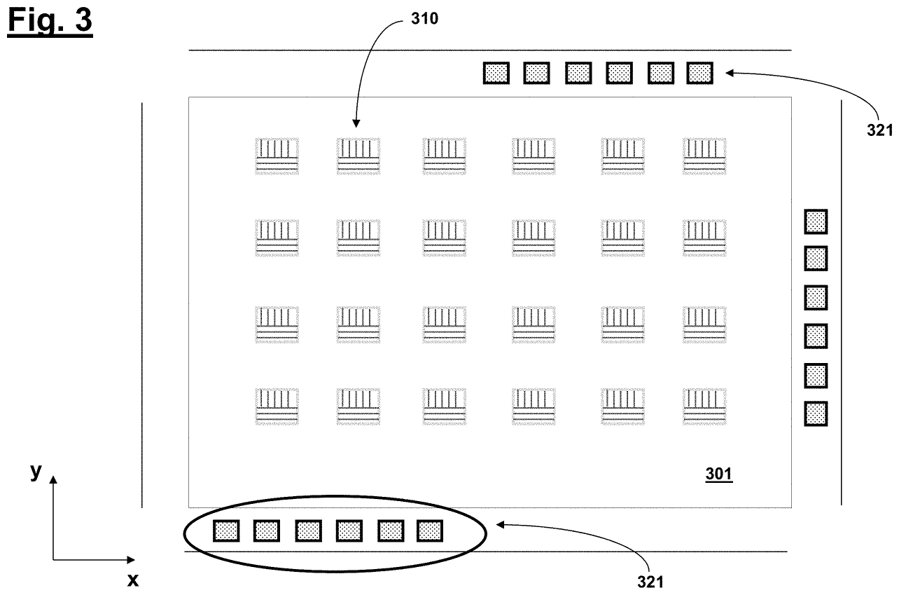

FIG. 3 shows, in a merely schematic and greatly simplified illustration, a wafer 301 in plan view, wherein both diverse used structures 310 and auxiliary structures 321 are situated on the wafer and wherein the auxiliary structures 321 are typically arranged outside the used structures 310 or in “scribe lines” (i.e. breaking lines or regions of the wafer) situated between the chips respectively produced.

According to the invention, then, a metrology target is used for implementing said auxiliary structures, in particular, wherein the metrology target has a periodic or quasi-periodic structure, wherein said structure is characterized by a plurality of parameters, wherein at least one of said parameters, in order to achieve the advantages described in the introduction, varies locally monotonically on a scale that is large in comparison with the operating wavelength of the measuring arrangement from FIG. 2. In this case, in particular, the maximum size of this variation over a distance of 5 μm can be less than 10%. In the case of application in a scatterometric arrangement, the maximum size of said variation over a distance corresponding to ten times an operating wavelength used during the intensity measurements can be less than 10%.

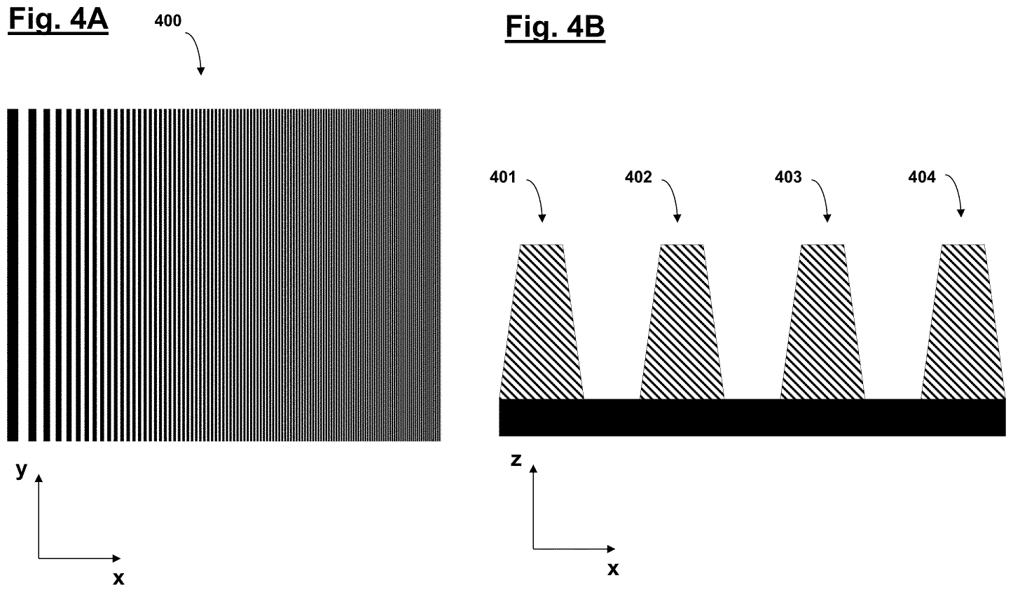

FIGS. 4A-4B show a schematic illustration for explaining one exemplary embodiment of such a metrology target, wherein here the locally monotonically varying parameter mentioned above is the pitch (i.e. the period). In this case, in FIG. 4A, each perpendicular web, for its part, is intended to contain the same plurality of (e.g. ten) webs each having an identical web width. FIG. 4B shows, with respect to the macroscopic plan view from FIG. 4A, a microscopic sectional view with such webs 401-404. As indicated in FIG. 4B, the period represented by the width of the webs decreases monotonically in the x direction (the period can decrease for example over the entire metrology target for instance from a value of 600 nm down to a value of 20 nm). However, as explained above, this local variation takes place on a scale that is large in comparison with the respective operating wavelength of the measuring arrangement, with the consequence that at each individual location of the structure, periodic boundary conditions for solving Maxwell's equations are still justified.

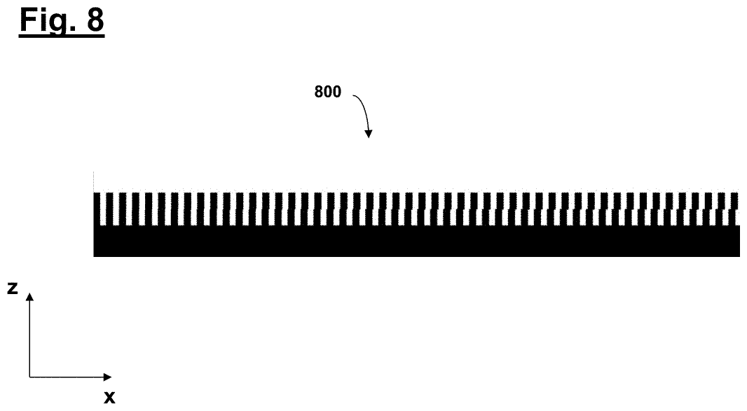

The invention is not restricted to the local variation of the pitch (i.e. of the period) within the metrology target as described in FIGS. 4A-4B. FIG. 8 shows a schematic illustration of a further embodiment of a metrology target 800 according to the invention, wherein here, in contrast to FIGS. 4A-4B, the overlay value is used as a locally varying parameter.

The configuration of the metrology target according to the invention as described above with reference to FIGS. 4A-4B can then be used, as described below, in particular, in multiple regards for breaking up disturbing correlations.

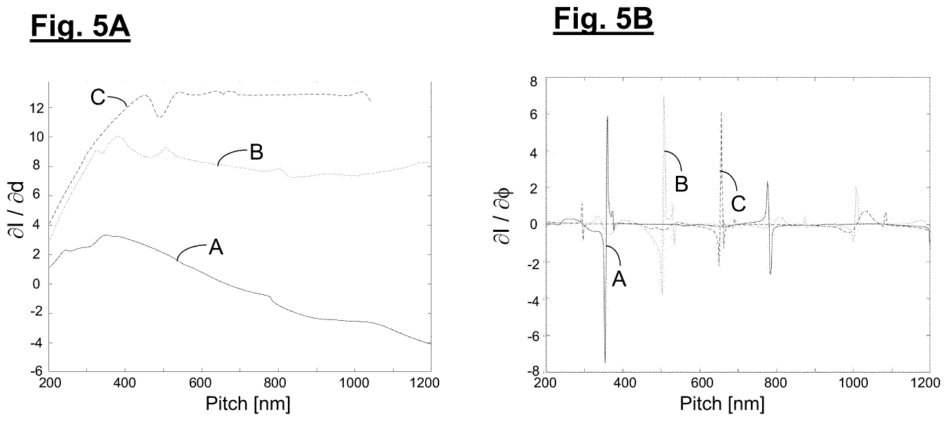

In accordance with one aspect described with reference to FIGS. 5A-5B, the metrology target can be used, in particular, to differentiate, on the basis of the intensity measurements carried out in the scatterometric arrangement, whether specific measurement signals are attributable to a faulty auxiliary structure or to a faulty alignment of the measurement arrangement.

In the diagram in FIG. 5A, the three curves “A”, “B” and “C” correspond to different measurement channels of the scatterometric measurement in the arrangement from FIG. 2, wherein these different measurement channels are characterized by mutually different combinations of wavelength, polarization and order of diffraction. The period (pitch) in nanometers (nm)—as the continuously varying parameter of the metrology target according to the invention, e.g. in accordance with the embodiment from FIGS. 4A-4B—is plotted on the horizontal axis. On the vertical axis, the partial derivative of the intensity I of the relevant measurement channel with respect to the etching depth d is plotted in FIG. 5A, whereas the partial derivative of the intensity I of the relevant measurement channel with respect to the tilt angle ϕ of the sample or of the metrology target is plotted in FIG. 5B (wherein the tilt angle ϕ denotes a tilt of the sample in the measuring arrangement). On account of the distinct difference between the curves, the intensity measurements carried out in the scatterometric arrangement can be taken as a basis for establishing whether the measurement signals obtained are attributable, if appropriate, to a faulty alignment of the sample with respect to the measurement arrangement.

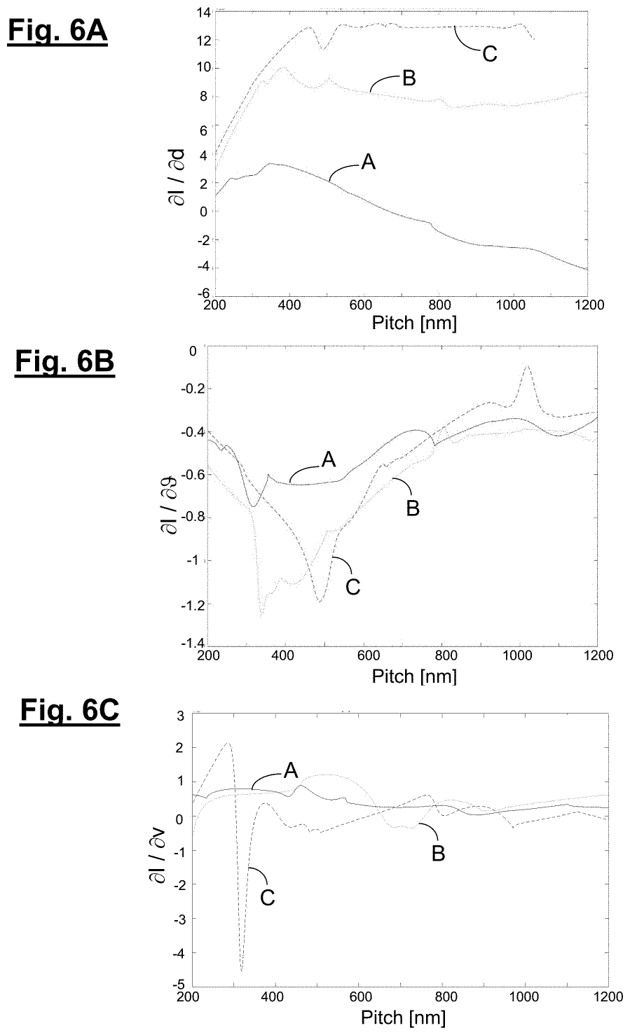

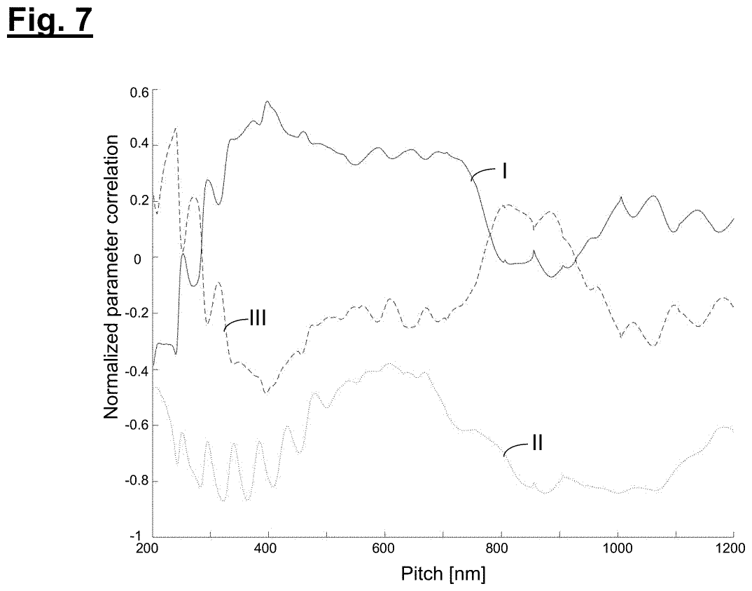

FIGS. 6A-6C and FIG. 7 show diagrams for explaining a further possible application of the invention. In accordance with this aspect, the metrology target according to the invention can be used for “breaking up” parameter correlations in so far as—as described below—respectively suitable regions of the metrology target can be identified in which specific profile parameters can be ascertained simultaneously.

In the diagram in FIG. 6A, once again the three curves “A”, “B” and “C” correspond to different measurement channels of the scatterometric measurement in the arrangement from FIG. 2, wherein these different measurement channels are characterized by mutually different combinations of wavelength, polarization and order of diffraction. The period (pitch) in nanometers (nm)—as the continuously varying parameter of the metrology target according to the invention, e.g. in accordance with the embodiment from FIGS. 4A-4B—is plotted on the horizontal axis. The partial derivative of the intensity I of the relevant measurement channel with respect to the etching depth d is plotted on the vertical axis. FIG. 6B and FIG. 6C show analogous diagrams in which instead the partial derivative of the intensity I of the relevant measurement channel with respect to the sidewall angle (FIG. 6B) and the partial derivative of the intensity I of the relevant measurement channel with respect to the ratio v of web width to period (FIG. 6C) are respectively plotted.

FIG. 7 shows the parameter correlations—resulting from the diagrams in FIGS. 6A-6C—on the basis of the formation of corresponding covariance matrices between two parameters in each case. In this respect, reference is made to Thomas A. Germer et al.: “Developing an uncertainty analysis for optical scatterometry Metrology, Inspection, and Process Control for Microlithography XXIII, J. A. Allgair, Ed., Proc. SPIE 7272, (2009). In FIG. 7, curve “I” describes the parameter correlation between etching depth and CD, curve “II” describes the parameter correlation between etching depth and sidewall angle, and curve “III” describes the parameter correlation between CD and sidewall angle. A value of the normalized correlation value of zero corresponds to a correlation between the respective parameters that is not present at all, while a correlation value having a small absolute value in the diagram in FIG. 7 indicates a still weak correlation and thus that a simultaneous determination of the relevant profile parameters is effected advantageously in this region of the metrology target. In FIG. 7 this holds true e.g. for the two parameters of etching depth and sidewall angle for a pitch value of approximately 600 nm.

The invention thus makes use here of the fact that despite a pronounced correlation—given in principle—e.g. of the parameters of etching depth and sidewall angle in the measurement signals obtained during the scatterometric measurement in the arrangement from FIG. 2, this correlation is not identical over the entire variation range of the locally varying parameter on the metrology target, since this variation of the correlation can be used for breaking the relevant parameter correlation, for instance by the sidewall angle being ascertained in one region and the etching depth in another region.

In a further field of application of the present invention, auxiliary or marker structures are also used in computer-generated holograms (CGHs). Such CGHs are used for example for the highly accurate testing of mirrors. In this case, the realization of a calibration of the CGHs that are used in mirror testing by using so-called complex-encoded CGHs is also known, inter alia, wherein at least one further “calibration functionality” for providing a reference wavefront that serves for calibration or error correction is encoded in one and the same CGH in addition to the “use functionality” (i.e. the CGH structure that is designed in accordance with the mirror shape for shaping the wavefront that mathematically corresponds to the test specimen shape) that is required for the actual test.

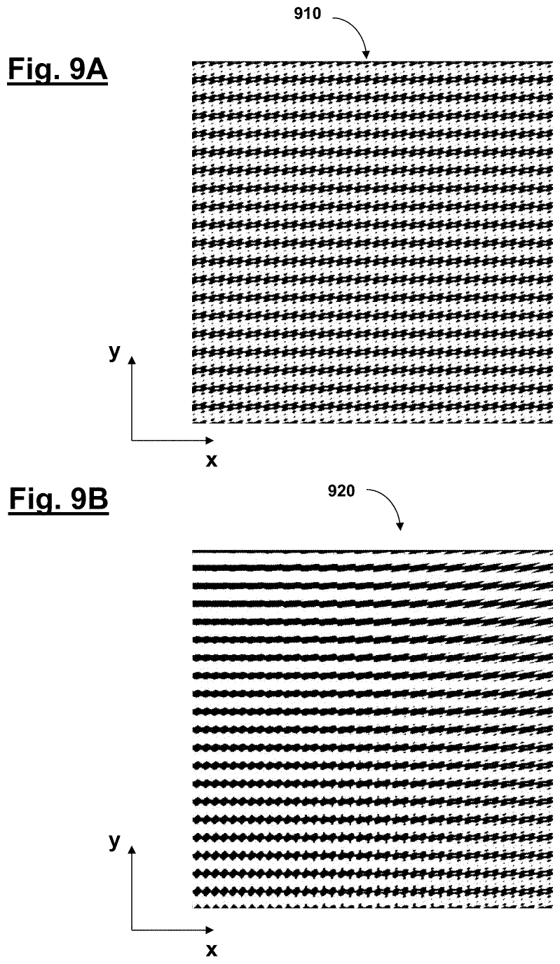

One problem that occurs here in practice is that in general numerous profile parameters (such as e.g. sidewall angles or feature size (CD) are required for completely determining the profile of a CGH (as illustrated e.g. in FIG. 9A as an excerpt for a CGH 910), wherein in this case, too, a profile parameter determination can firstly be effected on the basis of an auxiliary or marker structure which is fashioned more simply by virtue of a smaller number of parameters. As in the applications described above, a metrology target according to the invention can then be constituted in such a way that the corresponding, comparatively simple auxiliary structure is converted progressively into the actual used structure in order to be able to better measure the profile parameters analogously to the embodiments described above. This is illustrated schematically for a metrology target 920 in FIG. 9A, wherein the actual used structure (bottom right in FIG. 9B) with complex encoding is continuously converted into the line grating, shown at the top left in FIG. 9B, on the metrology target 920.

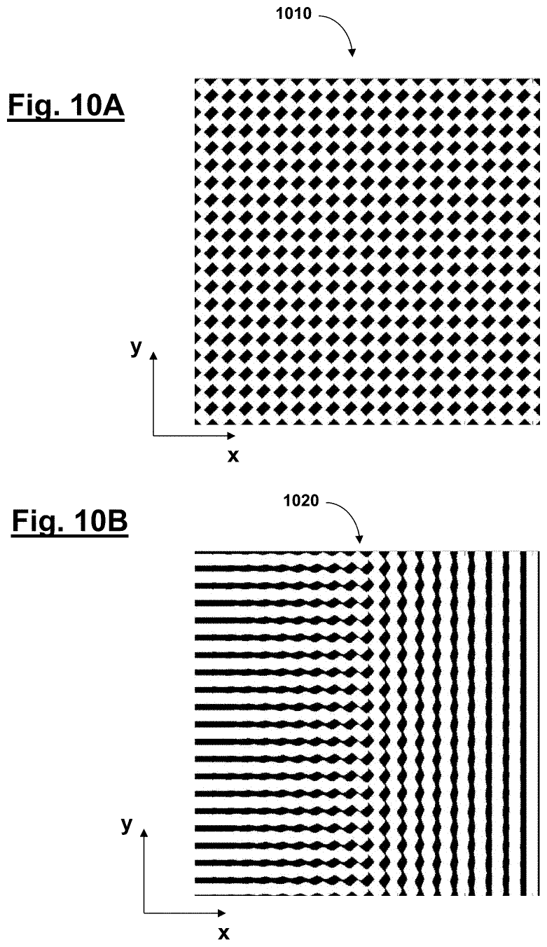

FIGS. 10A-10B show a further example, wherein here the complex encoded CGH 1010 illustrated in FIG. 10A as a used structure has a chequered pattern. FIG. 10B shows a suitable metrology target 1020, in which said pattern is converted continuously into a horizontal line pattern (on the left in FIG. 10B) or a vertical line pattern (on the right in FIG. 10B).

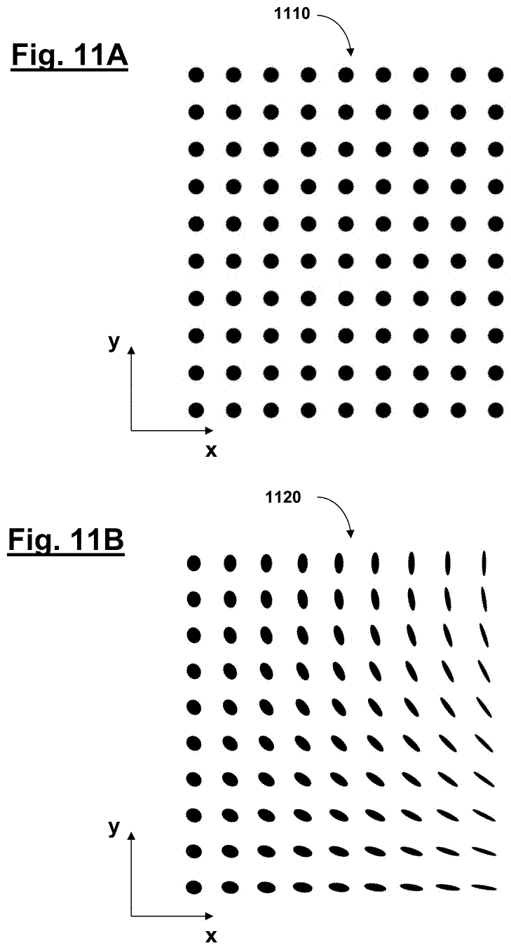

FIGS. 11A-11B show one example of an application of the above-described concept of the continuous conversion of patterns or structures in lithography. FIG. 11A schematically illustrates a regular arrangement 1110 of contact holes for electrically conductively connecting structures to one another. A typical characteristic parameter that is relevant in specific scenarios is the ellipticity of said contact holes. In accordance with FIG. 11B, a continuous conversion of a perfectly round geometry of the contact holes into geometries having a varying ellipticity is realized in an arrangement 1120.

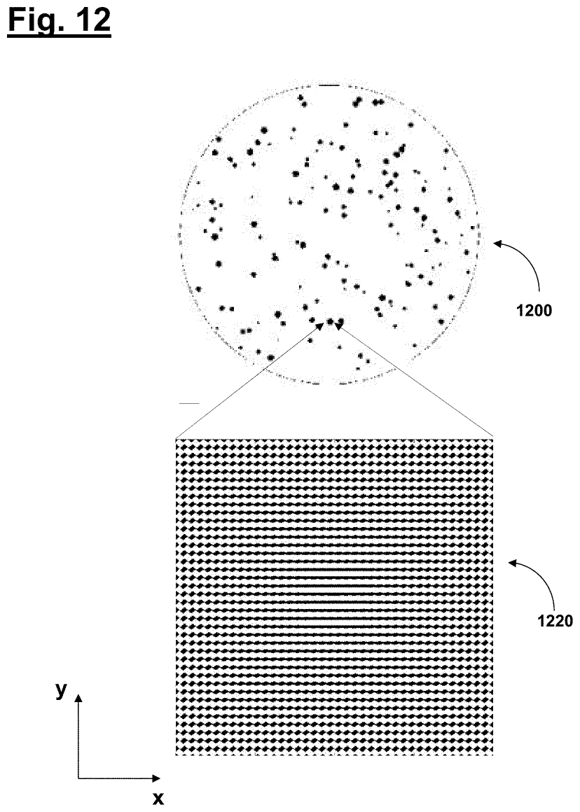

In advantageous embodiments of the invention, in accordance with a further aspect, as illustrated in FIG. 12, a marker structure 1220 is positioned in a region of a CGH 1200 which is not used anyway for the actual measurement (e.g. owing to disturbances of the measurement signal that occur in the relevant region as a result of reflections) (such regions being shown as black in FIG. 12). In this case, the relevant auxiliary or marker structure 1220—as likewise indicated in FIG. 12—can once again be configured with a constant or continuous transition to the used structure in the manner described above, wherein in the example in FIG. 12 a line pattern present in the central region of the auxiliary or marker structure 1220 is continuously converted into the surrounding, complex used structure.

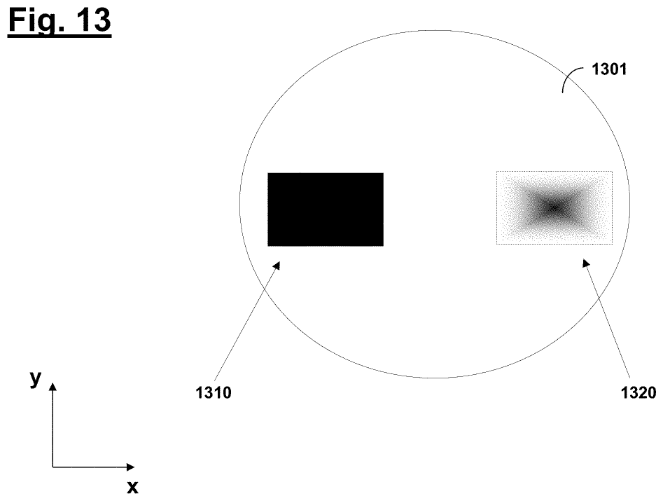

A further application of the invention arises from the fact that auxiliary structures in the form of alignment structures are also present on CGHs in addition to the actual metrology targets, wherein continuous transitions between the alignment structures and the used structures can be created in an advantageous manner here, too. FIG. 13 serves to explain this aspect. While an abrupt transition—indicated on the left in FIG. 13—between auxiliary or alignment structure 1310 and used structure 1301, from a production engineering standpoint, leads to undesired process variations and (for instance by way of shading effects during plasma etching) ultimately to an undesired modification of the used structures 1301, this effect can be avoided, as indicated on the right in FIG. 13, by a smooth, continuous transition according to the invention between auxiliary or alignment structure 1320 and used structure 1301.

Even though the invention has been described on the basis of specific embodiments, numerous variations and alternative embodiments are apparent to a person skilled in the art, for example by combination and/or exchange of features of individual embodiments. Accordingly, for the person skilled in the art, such variations and alternative embodiments are concomitantly encompassed by the present invention, and the scope of the invention is restricted only within the meaning of the appended patent claims and the equivalents thereof

What is claimed is:

1. A metrology target, comprising
a periodic or quasi-periodic structure,
wherein the structure is characterized by a plurality of parameters, wherein at least one of the parameters varies locally monotonically, and wherein a maximum size of the variation over a distance of 5 μm is less than 10% of a size of the at least one parameter; and
at least one used structure and at least one auxiliary structure,
wherein the auxiliary structure transitions progressively into the used structure with regard to the locally monotonically varying parameter.

2. The metrology target as claimed in claim 1, wherein the maximum size of the variation over a distance of 40 μm is less than 10%.

3. The metrology target as claimed in claim 1, wherein the maximum size of the variation over the distance is less than 1%.

4. The metrology target as claimed in claim 1, wherein the locally monotonically varying parameter is a geometric parameter.

5. The metrology target as claimed in claim 1, wherein the structure is further characterized by at least one constant parameter.

6. The metrology target as claimed in claim 1, wherein at least one of the parameters characterizing the structure is selected from the group consisting of pitch, sidewall angle and etching depth.

7. The metrology target as claimed in claim 1, configured for a diffraction-based determination of at least one profile parameter of a used structure on a structured element selected from the group consisting of a wafer, a mask and a computer-generated hologram (CGH) in a scatterometric measurement arrangement.

8. A computer-generated hologram (CGH), comprising a metrology target,
wherein the metrology target has a periodic or quasi-periodic structure; and
wherein the structure is characterized by a plurality of parameters, wherein at least one of the parameters varies locally monotonically, and wherein a maximum size of the variation over a distance of 5 μm is less than 10% of a size of the at least one parameter.

9. The CGH as claimed in claim 8, wherein the maximum size of the variation over a distance of 40 μm is less than 10%.

10. The CGH as claimed in claim 8, wherein the maximum size of the variation over the distance is less than 1%.

11. The CGH as claimed in claim 8, wherein the metrology target has at least one used structure and at least one auxiliary structure, and wherein the auxiliary structure transitions progressively into the used structure with regard to the locally monotonically varying parameter.

12. The CGH as claimed in claim 8, wherein the locally monotonically varying parameter is a geometric parameter.

13. The CGH as claimed in claim 8, wherein the structure is further characterized by at least one constant parameter.

14. The CGH as claimed in claim 8, wherein at least one of the parameters characterizing the structure is selected from the group consisting of pitch, sidewall angle and etching depth.

15. The CGH as claimed in claim 8, wherein the metrology target is configured for a diffraction-based determination of at least one profile parameter of a used structure on a structured element selected from the group consisting of a wafer, a mask and a CGH in a scatterometric measurement arrangement.

16. The CGH as claimed in claim 8, configured for testing a surface of a mirror by interferometric superimposition of a test wave directed onto the mirror by the CGH and a reference wave, wherein the metrology target is arranged in a region of the CGH that is unused during the interferometric superimposition.

17. A computer-generated hologram (CGH) comprising:
at least one used structure and
at least one alignment structure adjoining the used structure or embedded into the used structure,
wherein the alignment structure is configured to align the computer-generated hologram in relation to an interferometric test arrangement, and
wherein the used structure is converted continuously into the alignment structure with regard to at least one characteristic parameter.

18. A method for characterizing a structured element selected from the group consisting of a wafer, a mask and a CGH, comprising:
ascertaining a plurality of parameters characteristic of the structured element based on measurements of an intensity of electromagnetic radiation after diffraction of the radiation at the structured element, wherein the intensity measurements are carried out for at least one used structure and at least one auxiliary structure situated on a metrology target;
ascertaining the parameters based on intensity values measured during the intensity measurements for respectively different combinations of wavelength, polarization and/or order of diffraction, and also based on correspondingly calculated intensity values, to which a mathematical optimization method is applied;
wherein the metrology target has a periodic or quasi-periodic structure,
wherein the structure is characterized by a plurality of parameters, wherein at least one of the parameters varies locally monotonically, and wherein a maximum size of the variation over a distance of 5 μm is less than 10% of a size of the at least one parameter.

19. A device for characterizing a structured element in the form of a wafer, a mask or a CGH, configured to perform the method as claimed in claim 18.

20. A method for characterizing a structured element selected from the group consisting of a wafer, a mask and a computer-generated hologram (CGH), comprising:
ascertaining a plurality of parameters characteristic of the structured element based on measurements of an intensity of electromagnetic radiation after diffraction of the radiation at the structured element, wherein the intensity measurements are carried out for at least one used structure and at least one auxiliary structure situated on a metrology target;
ascertaining the parameters based on intensity values measured during the intensity measurements for respectively different combinations of wavelength, polarization and/or order of diffraction, and also based on correspondingly calculated intensity values, to which a mathematical optimization method is applied;
wherein the metrology target has a periodic or quasi-periodic structure;
wherein the structure is characterized by a plurality of parameters, wherein at least one of the parameters varies locally monotonically, and wherein a maximum size of the variation over a distance corresponding to ten times an operating wavelength used during the intensity measurements is less than 10% of a size of the at least one parameter.

21. A device for characterizing a structured element in the form of a wafer, a mask or a CGH, configured to perform the method as claimed in claim 20.
